(19) United States
(12) Patent Application Publication
(10) Pub. No.: US 2026/0065990 A1
(43) Pub. Date: Mar. 5, 2026

(54) MEMORY DEVICE AND MEMORY SYSTEM

(71) Applicant: MACRONIX INTERNATIONAL CO., LTD., HSINCHU (TW)

(72) Inventors: Po-Hao TSENG, Taichung City (TW); Tian-Cih BO, Zhubei City (TW)

(21) Appl. No.: 18/974,617

(22) Filed: Dec. 9, 2024

Related U.S. Application Data
(60) Provisional application No. 63/689,874, filed on Sep. 3, 2024.

(51) Int. Cl. G11C 16/04; H03M 7/16

(52) U.S. Cl. CPC G11C 16/0483; H03M 7/165

(57) ABSTRACT

A memory device includes a memory string. The memory string is configured to stored store data, and compare input data with the store data to generate a string current signal, wherein the memory string comprises memory cells, the memory cells comprises switch elements coupled in series, when a quantized value of the input data is equal to a quantized value of the stored data, a first switch element of the switch elements is turned on and the string current signal has a first current level, and when the quantized value of the input data is different from the quantized value of the stored data, the first switch element of the switch elements is turned off and the string current signal has a second current level lower than the first current level.

### CROSS-REFERENCE TO RELATED APPLICATION

This application claims priority to U.S. Provisional Application No. 63/689,874, filed Sep. 3, 2024, which is herein incorporated by reference in its entirety.

### BACKGROUND

### Technical Field

The present disclosure relates to a memory technique. More particularly, the present disclosure relates to a memory device and a memory system.

### Description of Related Art

Data searching is essential function in artificial intelligence application. Thermometer encoding can be used in artificial intelligence engine, and can be implemented by memory devices. Thus, techniques associated with the designing memory devices for thermometer encoding with high efficiency are important issues in the field.

### SUMMARY

The present disclosure provides a memory device. The memory device includes a memory string. The memory string is configured to stored store data, and compare input data with the store data to generate a string current signal, wherein the memory string comprises a plurality of memory cells, the plurality of memory cells comprises a plurality of switch elements coupled in series, when a quantized value of the input data is equal to a quantized value of the stored data, a first switch element of the plurality of switch elements is turned on and the string current signal has a first current level, and when the quantized value of the input data is different from the quantized value of the stored data, the first switch element of the plurality of switch elements is turned off and the string current signal has a second current level lower than the first current level.

In some embodiments, the memory string comprises a first memory cell and a second memory cell, the first memory cell comprises a first switch element and a second switch element, the second memory cell comprises a third switch element and a fourth switch element, when the first memory cell and the second memory cell have a first logic value and a second logic value respectively, the third switch element, the second switch element, the first switch element and the fourth switch element have a first threshold voltage level, a second threshold voltage level, a third threshold voltage level, and a fourth threshold voltage level, respectively, and the first threshold voltage level, the second threshold voltage level, the third threshold voltage level, and the fourth threshold voltage level are different from each other.

In some embodiments, the first switch element, the second switch element, the third switch element and the fourth switch element are configured to receive a first word line signal, a second word line signal, a third word line signal and a fourth word line signal, respectively, the first word line signal and the second word line signal are configured to carry a first search bit, the third word line signal and the fourth word line signal are configured to carry a second search bit, and when the second search bit has the second logic value, each of the first search bit and the first memory cell has the first logic value, and each of the third switch element and the fourth switch element has the first threshold voltage level, the string current signal has the first current level.

In some embodiments, the first logic value is larger than the second logic value.

In some embodiments, when the first search bit has a third logic value and the first memory cell has the first logic value, the first switch element is turned off, and the third logic value is larger than the first logic value.

In some embodiments, when the first search bit has the first logic value and the first memory cell has the third logic value, the second switch element is turned off.

In some embodiments, when the second search bit has the second logic value, each of the first search bit and the first memory cell has the third logic value, and each of the third switch element and the fourth switch element has the first threshold voltage level, the string current signal has the first current level.

In some embodiments, when the first search bit and the first memory cell have the first logic value and the third logic value, respectively, the string current signal has the second current level.

In some embodiments, when the second search bit has the second logic value and each of the third switch element and the fourth switch element has the first threshold voltage level, each of the third switch element and the fourth switch element is turned on.

In some embodiments, the memory string further comprises at least one switch element coupled in series with the plurality of switch elements, and at least one control terminal of the at least one switch element has a clamp voltage level, to clamp the string current signal.

The present disclosure provides a memory device. The memory device includes a memory string. The memory string configured to store stored data, and configured to receive a plurality of word line signals carrying input data, to compare the input data with the stored data to generate a string current signal, wherein the memory string comprises a first memory cell, the first memory cell comprises a first switch element and a second switch element coupled in series, the first switch element and the second switch element are configured to receive a first word line signal of the plurality of word line signals and a second word line signal of the plurality of word line signals, respectively, when the stored data have a first quantized value, the first switch element and the second switch element respectively have a first threshold voltage level and a second threshold voltage level, when the input data have the first quantized value, the first word line signal and the second word line signal respectively have a first voltage level and a second voltage level, and when the input data have a second quantized value different from the first quantized value, the first word line signal and the second word line signal respectively have the second voltage level and the first voltage level.

In some embodiments, when the stored data and the input data have the first quantized value and the second quantized value, respectively, the second switch element is turned off and the first switch element is turned on.

In some embodiments, when the stored data and the input data have the second quantized value and the first quantized value, respectively, the first switch element is turned off and the second switch element is turned on.

In some embodiments, when each of the stored data and the input data has the first quantized value, the string current signal has a first current level, and when the stored data and the input data have the first quantized value and the second quantized value, respectively, the string current signal has a second current level smaller than the first current level.

In some embodiments, the first word line signal and the second word line signal are configured to carry a first search bit, the memory string further comprises a second memory cell, the second memory cell comprises a third switch element and a fourth switch element coupled in series, the third switch element and the fourth switch element are configured to receive a third word line signal and a fourth word line signal of the plurality of word line signals, respectively, the third word line signal and the fourth word line signal are configured to carry a second search bit, when the second memory cell has a first logic value, each of the third switch element and the fourth switch element has a third threshold voltage level, and the third threshold voltage level is smaller than each of the first threshold voltage level and the second threshold voltage level.

In some embodiments, when the second memory cell has the first logic value, the second search bit has a second logic value, and each of the first memory cell and the first search bit has a third logic value, the string current signal has the first current level, and the first logic value, the second logic value and the third logic value are different from each other.

In some embodiments, when the second memory cell has the first logic value, the second search bit has a second logic value, and the first memory cell and the first search bit have a third logic value and a fourth logic value, respectively, the string current signal has the second current level, and the first logic value, the second logic value, the third logic value and the fourth logic value are different from each other.

The present disclosure provides a memory system. The memory system includes a plurality of memory chunks. The plurality of memory chunks configured to receive a plurality of string select line signals, wherein the plurality of memory chunks at least comprise a first memory string configured to store first stored data and a second memory string configured to store second stored data, the first memory string is configured to compare the first stored data and input data to generate a first string current signal, the second memory string is configured to compare the second stored data and the input data to generate a second string current signal, in response to a quantized value of the input data being equal to a quantized value of the first stored data, the first string current signal has a first current level, and in response to the quantized value of the input data being different from the quantized value of the second stored data, the second string current signal has a second current level lower than the first current level.

In some embodiments, the plurality of memory chunks further comprise a third memory string configured to store third stored data, and the third memory string is configured to compare the third stored data and the input data to generate a third string current signal.

In some embodiments, the first memory string includes a first memory cell and a second memory cell, the third memory string includes a third memory cell and a fourth memory cell, when the first memory cell has a first logic value, each of the second memory cell and the fourth memory cell has a second logic value, and the third memory cell has a third logic value, each of the first string current signal and the third string current signal has the first current level, and the first logic value, the second logic value and the third logic value are different from each other.

It is to be understood that both the foregoing general description and the following detailed description are examples, and are intended to provide further explanation of the disclosure as claimed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic diagram of a part of a memory device illustrated according to some embodiments of present disclosure.

FIG. 1B is a schematic diagram of distributions of the threshold voltage levels of the memory cells, illustrated according to some embodiments of present disclosure.

FIG. 1C is a schematic diagram of the memory cells performing the one-hot encoding operation, illustrated according to some embodiments of present disclosure.

FIG. 1D is a schematic diagram of the memory cells performing the one-hot encoding operation, illustrated according to some embodiments of present disclosure.

FIG. 1E is a schematic diagram of the memory cells performing the one-hot encoding operation, illustrated according to some embodiments of present disclosure.

FIG. 2A is a table of the one-hot encoding of feature data, illustrated according to some embodiments of present disclosure.

FIG. 2B is a table of the one-hot encoding of feature data, illustrated according to some embodiments of present disclosure.

FIG. 3A to FIG. 3F and FIG. 4A to FIG. 4B are schematic diagrams of the memory string performing search operations, illustrated according to some embodiments of present disclosure.

FIG. 5A is a schematic diagram of a memory system illustrated according to some embodiments of present disclosure.

FIG. 5B is a schematic diagram of further details of the memory system performing the search operation, illustrated according to some embodiments of present disclosure.

FIG. 5C is a schematic diagram of further details of the memory system performing the search operation, illustrated according to some embodiments of present disclosure.

### DETAILED DESCRIPTION

In the present disclosure, when an element is referred to as “connected” or “coupled”, it may mean “electrically connected” or “electrically coupled”. “Connected” or “coupled” can also be used to indicate that two or more components operate or interact with each other. In addition, although the terms “first”, “second”, and the like are used in the present disclosure to describe different elements, the terms are used only to distinguish the elements or operations described in the same technical terms. The use of the term is not intended to be a limitation of the present disclosure.

Unless otherwise defined, all terms (including technical and scientific terms) used in the present disclosure have the same meaning as commonly understood by the ordinary skilled person to which the concept of the present invention belongs. It will be further understood that terms (such as those defined in commonly used dictionaries) should be interpreted as having a meaning consistent with its meaning in the related technology and/or the context of this specification and not it should be interpreted in an idealized or overly formal sense, unless it is clearly defined as such in this article.

The terms used in the present disclosure are only used for the purpose of describing specific embodiments and are not intended to limit the embodiments. As used in the present disclosure, the singular forms “a”, “one” and “the” are also intended to include plural forms, unless the context clearly indicates otherwise. It will be further understood that when used in this specification, the terms “comprises (comprising)” and/or “includes (including)” designate the existence of stated features, steps, operations, elements and/or components, but the existence or addition of one or more other features, steps, operations, elements, components, and/or groups thereof are not excluded.

Hereinafter multiple embodiments of the present disclosure will be disclosed with schema, as clearly stated, the details in many practices it will be explained in the following description. It should be appreciated, however, that the details in these practices is not applied to limit the present disclosure. Also, it is to say, in some embodiments of the present disclosure, the details in these practices are non-essential. In addition, for the sake of simplifying schema, some known usual structures and element in the drawings by a manner of simply illustrating for it.

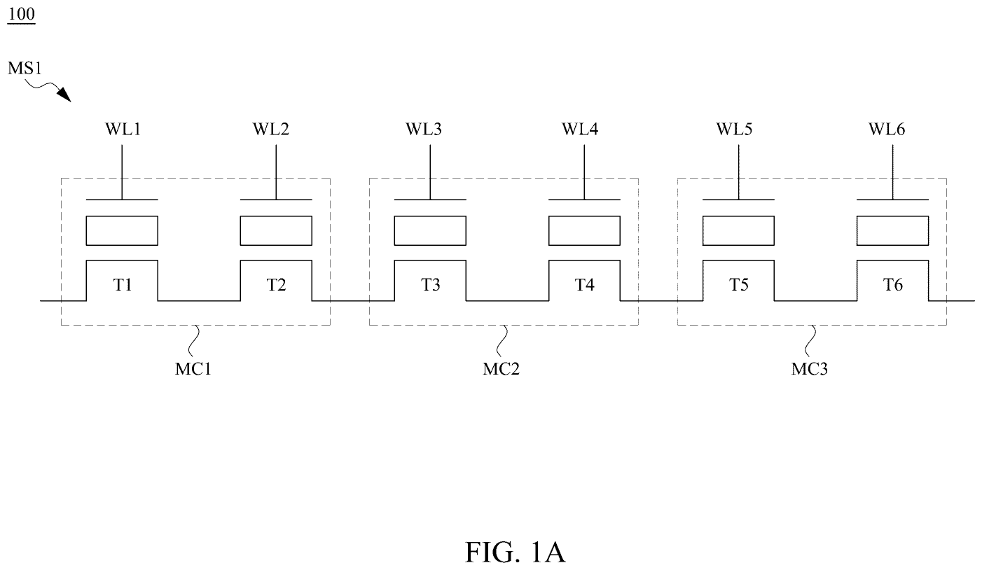

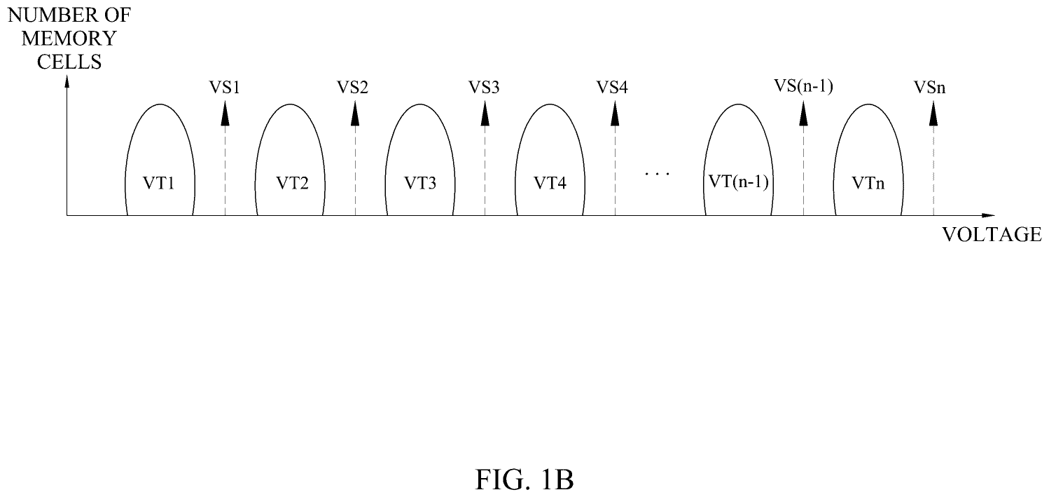

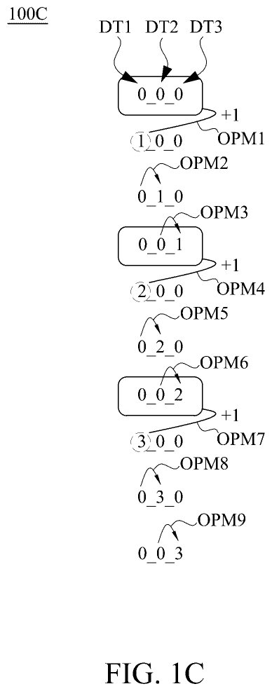

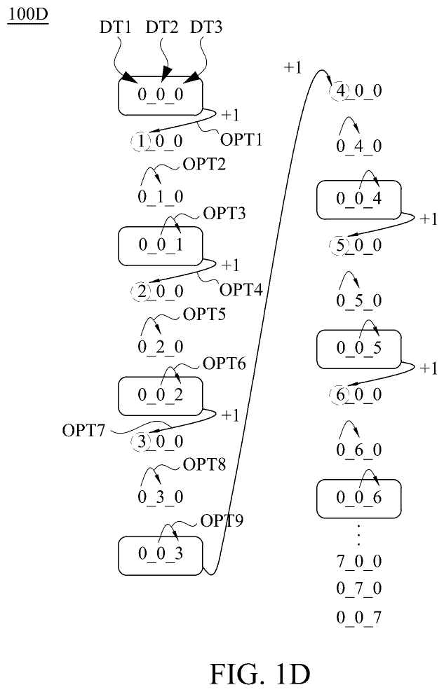

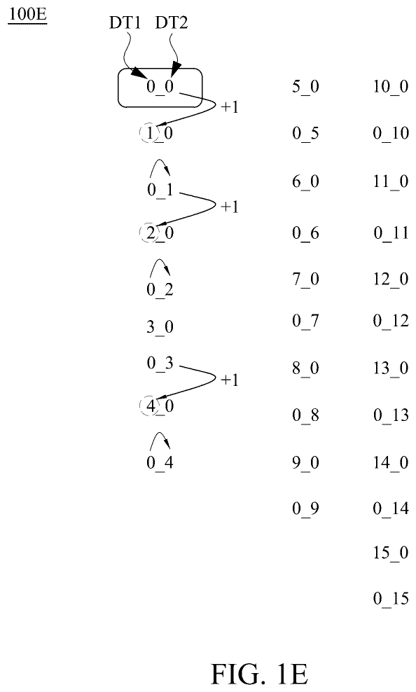

FIG. 1A are schematic diagrams of a part of a memory device 100, illustrated according to some embodiments of present disclosure. In some embodiments, the memory device 100 includes multiple memory strings, such as the memory string MS1 shown in FIG. 1A. The memory string MS1 can includes multiple memory cells, such as memory cells MC1-MC3. In some embodiments, the memory cells MC1-MC3 are configured to store stored data bits DT1-DT3.

As shown in FIG. 1A, the memory cell MC1 includes switch elements T1 and T2, the memory cell MC2 includes switch elements T3 and T4, and the memory cell MC3 includes switch elements T5 and T6. The switch elements T1-T6 are coupled in series and are arranged in order. In various embodiments, the switch elements T1-T6 can be implemented by N-type metal-oxide-semiconductor (NMOS) transistors, and can also be implemented by P-type metal-oxide-semiconductor (PMOS) transistors.

In some embodiments, control terminals of the switch elements T1-T6 are configured to receive the word line signals WL1-WL6, respectively. The word line signals WL1 and WL2 are configured to carry a search bit SB1, the word line signals WL3 and WL4 are configured to carry a search bit SB2, and the word line signals WL5 and WL6 are configured to carry a search bit SB3.

In some embodiments, in response to logic values of the stored data bits DT1-DT3, the switch elements T1-T6 have corresponding threshold voltage levels. In response to logic values of the search bits SB1-SB3, the word line signals WL1-WL6 have corresponding voltage levels. Further details regarding the voltage levels are described below with the embodiments associated with FIG. 1B.

FIG. 1B is a schematic diagram of distributions of the threshold voltage levels of the memory cells, illustrated according to some embodiments of present disclosure. A horizontal axis in FIG. 1B corresponds to voltages, and the vertical horizontal axis in FIG. 1B corresponds to quantities of the memory cells.

In various embodiments, for a positive integer n, the switch element can have one of threshold voltage levels VT1-VTn, and the word line signal can have one of voltage levels VS1-VSn. As shown in FIG. 1B, the threshold voltage levels VT1-VTn are arranged in order along the horizontal axis. The voltage level VS1 is larger than the threshold voltage level VT1 and is smaller than the threshold voltage level VT2. The voltage level VS2 is larger than the threshold voltage level VT2 and is smaller than the threshold voltage level VT3, and so on. The voltage level VS(n−1) is larger than the threshold voltage level VT(n−1) and is smaller than the threshold voltage level VTn. The voltage level VSn is larger than the threshold voltage level VTn.

When the stored data bit DT1 has a logic value 0, the switch elements T1 and T2 have the threshold voltage levels VT1 and VTn, respectively. When the stored data bit DT1 has a logic value 1, the switch elements T1 and T2 have the threshold voltage levels VT2 and VT(n−1), respectively, and so on. When the stored data bit DT1 has a logic value (n−1), the switch elements T1 and T2 have the threshold voltage levels VTn and VT1, respectively. When the stored data bit DT1 has a “don't care” logic value X, each of the switch elements T1 and T2 has the threshold voltage level VT1, respectively. In some embodiments, the “don't care” logic value X is indicated as an arbitrary logic value during storage.

On the other hand, when the search bit SB1 has the logic value 0, the word line signals WL1 and WL2 have the voltage levels VS1 and VSn, respectively. When the search bit SB1 has the logic value 1, the word line signals WL1 and WL2 have the voltage levels VS2 and VS(n−1), respectively. When the search bit SB1 has the logic value 2, the word line signals WL1 and WL2 have the voltage levels VS3 and VS(n−2), respectively, and so on. When the search bit SB1 has the logic value (n−1), the word line signals WL1 and WL2 have the voltage levels VSn and VS1, respectively. When the search bit SB1 has a wildcard logic value, each of the word line signals WL1 and WL2 have the voltage levels VSn. In some embodiments, the wildcard logic value is indicated as an arbitrary logic value during input.

In some embodiments, when a threshold voltage level of a switch element is smaller than a voltage level of a corresponding word line signal, the switch element is turned on. When the threshold voltage level of the switch element is smaller than the voltage level of the corresponding word line signal, the switch element is turned off. For example, when the switch element T1 has the threshold voltage level VT1 and the word line signal WL1 has the voltage level VS1, the switch element T1 is turned on. When the switch element T1 has the threshold voltage level VT2 and the word line signal WL1 has the voltage level VS1, the switch element T1 is turned off.

For other memory cells, the relationship between the logic values and the voltage levels are similar with the relationship described above. For example, for the memory cell MC2, when the stored data bit DT2 has the logic value 0, the switch elements T3 and T4 have the threshold voltage levels VT1 and VTn, respectively. When the search bit SB2 has the logic value 0, the word line signals WL3 and WL4 have the voltage levels VS1 and VSn, respectively. Therefore, for brevity, some descriptions are not repeated.

In various embodiments, the memory cells MC1-MC3 can be implemented by various types of memory cells, such as multi-level cells (MLC), trinary-level cells (TLC), Quad-level cells (QLC), and has corresponding encoding operation and thermometer coding rule. Further details regarding the thermometer coding rule are described below with the embodiments associated with FIG. 1C to FIG. 1E.

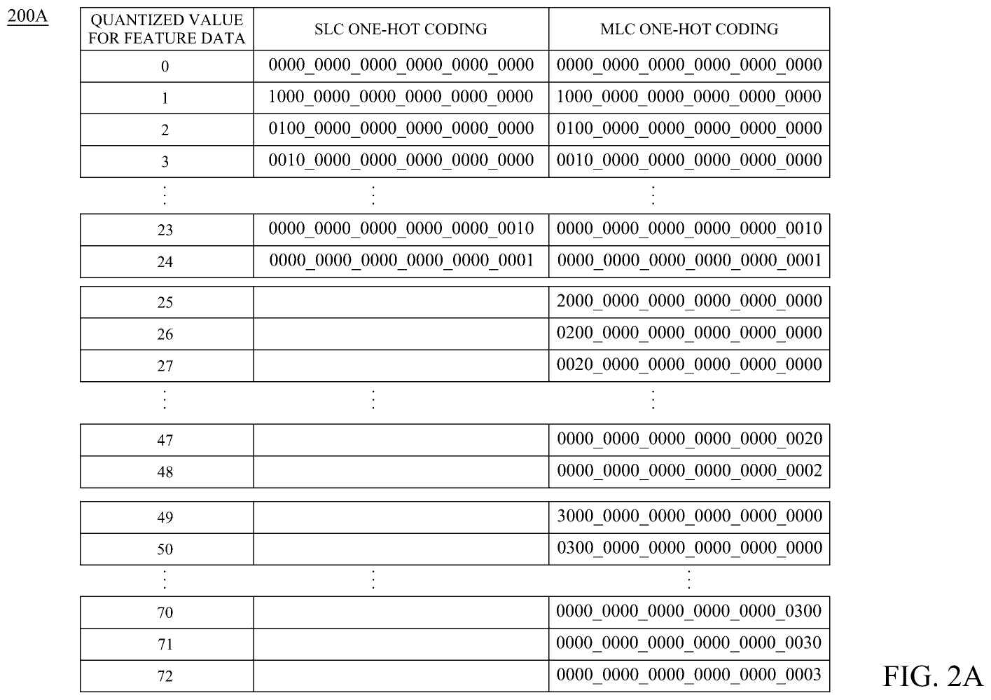

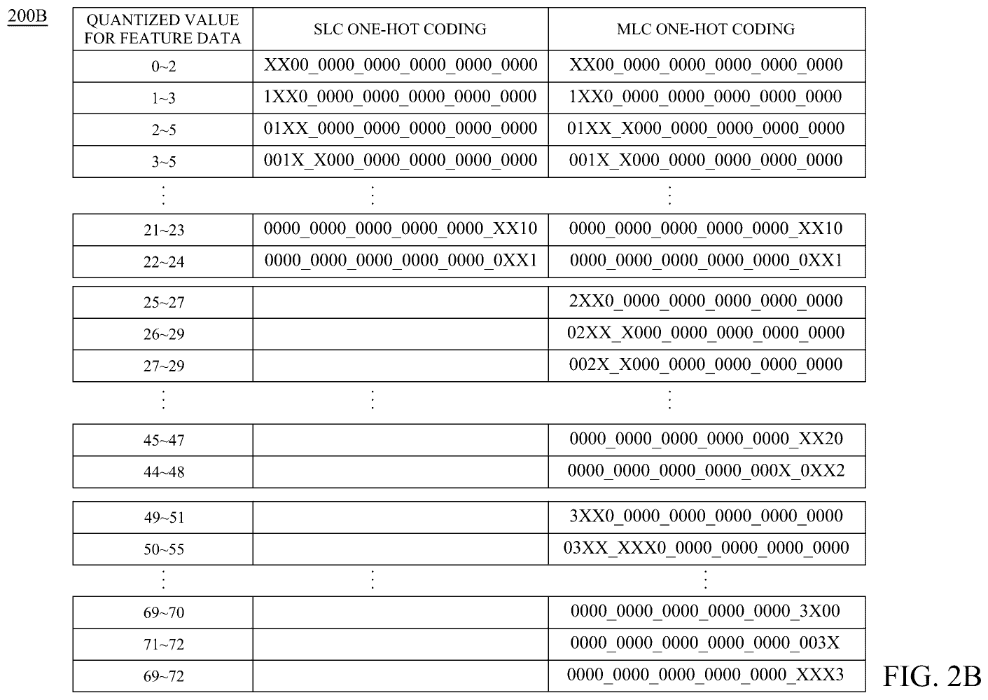

FIG. 1C is a schematic diagram 100C of the memory cells performing the one-hot encoding operation, illustrated according to some embodiments of present disclosure. Referring to FIG. 1A and FIG. 1C, in the embodiment shown in FIG. 1C, the memory cells MC1-MC3 are implemented by MLC. Referring to FIG. 1B and FIG. 1C, in the embodiment shown in FIG. 1C, the positive integer n is equal to 4. In some embodiments, the processor can perform calculations to the logic values of the data bits by a feature extractor in an artificial intelligence (AI), to generate corresponding quantized values. For example, the processor can transform the logic values into the quantized values according to the tables shown in FIG. 2A and FIG. 2B.

In the embodiment shown in FIG. 1C, three numbers separated by underlines correspond to the logic values of the stored data bits DT1-DT3, respectively. The memory cells MC1-MC3 can perform the operations OPM1-OPM9 to adjust the logic values of the stored data bits DT1-DT3.

Before the operation OPM1, each of the stored data bits DT1-DT3 has the logic value 0. Correspondingly, the switch elements T1-T6 have the threshold voltage levels VT1, VT4, VT1, VT4, VT1 and VT4, respectively. At this moment, the memory cells MC1-MC3 has a quantized value 0.

During the operation OPM1, the switch elements T1 and T2 are adjusted to the threshold voltage levels VT2 and VT3, respectively, such that the switch elements T1-T6 have the threshold voltage levels VT2, VT3, VT1, VT4, VT1 and VT4, respectively. Correspondingly, the stored data bits DT1-DT3 have the logic values 1, 0 and 0, respectively. At this moment, the memory cells MC1-MC3 has a quantized value 1.

During the operation OPM2, the switch elements T1-T4 are adjusted to the threshold voltage levels VT1, VT4, VT2 and VT3, respectively, such that the switch elements T1-T6 have the threshold voltage levels VT1, VT4, VT2, VT3, VT1 and VT4, respectively. Correspondingly, the stored data bits DT1-DT3 have the logic values 0, 1 and 0, respectively. Alternatively stated, the logic value 1 is shifted from the memory cell MC1 to the memory cell MC2. At this moment, the memory cells MC1-MC3 has a quantized value 2.

During the operation OPM3, the switch elements T3-T6 are adjusted to the threshold voltage levels VT1, VT4, VT2 and VT3, respectively, such that the switch elements T1-T6 have the threshold voltage levels VT1, VT4, VT1, VT4, VT2 and VT3, respectively. Correspondingly, the stored data bits DT1-DT3 have the logic values 0, 0 and 1, respectively. Alternatively stated, the logic value 1 is shifted from the memory cell MC2 to the memory cell MC3. At this moment, the memory cells MC1-MC3 has a quantized value 3.

During the operation OPM4, the switch elements T1, T2, T5 and T6 are adjusted to the threshold voltage levels VT3, VT2, VT1 and VT4, respectively, such that the switch elements T1-T6 have the threshold voltage levels VT3, VT2, VT1, VT4, VT1 and VT4, respectively. Correspondingly, the stored data bits DT1-DT3 have the logic values 2, 0 and 0, respectively. At this moment, the memory cells MC1-MC3 has a quantized value 4.

During the operation OPM5, the switch elements T1-T4 are adjusted to the threshold voltage levels VT1, VT4, VT3 and VT2, respectively, such that the switch elements T1-T6 have the threshold voltage levels VT1, VT4, VT3, VT2, VT1 and VT4, respectively. Correspondingly, the stored data bits DT1-DT3 have the logic values 0, 2 and 0, respectively. Alternatively stated, the logic value 2 is shifted from the memory cell MC1 to the memory cell MC2. At this moment, the memory cells MC1-MC3 has a quantized value 5.

During the operation OPM6, the switch elements T3-T6 are adjusted to the threshold voltage levels VT1, VT4, VT3 and VT2, respectively, such that the switch elements T1-T6 have the threshold voltage levels VT1, VT4, VT1, VT4, VT3 and VT2, respectively. Correspondingly, the stored data bits DT1-DT3 have the logic values 0, 0 and 2, respectively. Alternatively stated, the logic value 2 is shifted from the memory cell MC2 to the memory cell MC3. At this moment, the memory cells MC1-MC3 has a quantized value 6.

During the operation OPM7, the switch elements T1, T2, T5 and T6 are adjusted to the threshold voltage levels VT1, VT4, VT1 and VT4, respectively, such that the switch elements T1-T6 have the threshold voltage levels VT4, VT1, VT1, VT4, VT1 and VT4, respectively. Correspondingly, the stored data bits DT1-DT3 have the logic values 3, 0 and 0, respectively. At this moment, the memory cells MC1-MC3 has a quantized value 7.

During the operation OPM8, the switch elements T1-T4 are adjusted to the threshold voltage levels VT1, VT4, VT4 and VT1, respectively, such that the switch elements T1-T6 have the threshold voltage levels VT1, VT4, VT4, VT1, VT1 and VT4, respectively. Correspondingly, the stored data bits DT1-DT3 have the logic values 0, 3 and 0, respectively. Alternatively stated, the logic value 3 is shifted from the memory cell MC1 to the memory cell MC2. At this moment, the memory cells MC1-MC3 has a quantized value 8.

During the operation OPM8, the switch elements T3-T6 are adjusted to the threshold voltage levels VT1, VT4, VT4 and VT1, respectively, such that the switch elements T1-T6 have the threshold voltage levels VT1, VT4, VT1, VT4, VT4 and VT1, respectively. Correspondingly, the stored data bits DT1-DT3 have the logic values 0, 0 and 3, respectively. Alternatively stated, the logic value 3 is shifted from the memory cell MC2 to the memory cell MC3. At this moment, the memory cells MC1-MC3 has a quantized value 9.

FIG. 1D is a schematic diagram 100D of the memory cells performing the one-hot encoding operation, illustrated according to some embodiments of present disclosure. Referring to FIG. 1A and FIG. 1D, in the embodiment shown in FIG. 1D, the memory cells MC1-MC3 are implemented by TLC. Referring to FIG. 1B and FIG. 1D, in the embodiment shown in FIG. 1D, the positive integer n is equal to 8.

In the embodiment shown in FIG. 1D, three numbers separated by underlines correspond to the logic values of the stored data bits DT1-DT3, respectively. The memory cells MC1-MC3 can perform the operations OPT1-OPT9 to adjust the logic values of the stored data bits DT1-DT3.

Before the operation OPT1, each of the stored data bits DT1-DT3 has the logic value 0. Correspondingly, the switch elements T1-T6 have the threshold voltage levels VT1, VT8, VT1, VT8, VT1 and VT8, respectively. At this moment, the memory cells MC1-MC3 has a quantized value 0.

During the operation OPT1, the switch elements T1 and T2 are adjusted to the threshold voltage levels VT2 and VT7, respectively, such that the switch elements T1-T6 have the threshold voltage levels VT2, VT7, VT1, VT8, VT1 and VT8, respectively. Correspondingly, the stored data bits DT1-DT3 have the logic values 1, 0 and 0, respectively. At this moment, the memory cells MC1-MC3 has a quantized value 1.

The operations OPT2-OPT9 are similar with the operations OPM2-OPM9 shown in FIG. 1C. Therefore, for brevity, some descriptions are not repeated. The difference between the operations OPT2-OPT9 and the operations OPM2-OPM9 is that, in the operations shown in FIG. 1D, when a memory cell has the logic value 0, two switch elements of the memory cell have the threshold voltage levels VT1 and VT8, respectively. When the memory cell has the logic value 1, the two switch elements of the memory cell have the threshold voltage levels VT2 and VT7, respectively. When the memory cell has the logic value 2, the two switch elements of the memory cell have the threshold voltage levels VT3 and VT6, respectively. When the memory cell has the logic value 3, the two switch elements of the memory cell have the threshold voltage levels VT4 and VT5, respectively.

Furthermore, as shown in FIG. 1D, the stored data bits DT1-DT3 can also be adjusted to the logic values 4-7 by operations similar with the operations OPT1-OPT9, and have corresponding threshold voltage levels and the quantized values.

Specifically, when the stored data bits DT1-DT3 have the logic values 4, 0 and 0, respectively, the switch elements T1-T6 has the threshold voltage levels VT5, VT4, VT1, VT8, VT1 and VT8, respectively, and the stored data bits DT1-DT3 have a quantized value 10.

When the stored data bits DT1-DT3 have the logic values 0, 4 and 0, respectively, the switch elements T1-T6 has the threshold voltage levels VT1, VT8, VT5, VT4, VT1 and VT8, respectively, and the stored data bits DT1-DT3 have a quantized value 11.

When the stored data bits DT1-DT3 have the logic values 0, 0 and 4, respectively, the switch elements T1-T6 has the threshold voltage levels VT1, VT8, VT1, VT8, VT5 and VT4, respectively, and the stored data bits DT1-DT3 have a quantized value 12.

When the stored data bits DT1-DT3 have the logic values 5, 0 and 0, respectively, the switch elements T1-T6 has the threshold voltage levels VT6, VT3, VT1, VT8, VT1 and VT8, respectively, and the stored data bits DT1-DT3 have a quantized value 13.

When the stored data bits DT1-DT3 have the logic values 0, 5 and 0, respectively, the switch elements T1-T6 has the threshold voltage levels VT1, VT8, VT6, VT3, VT1 and VT8, respectively, and the stored data bits DT1-DT3 have a quantized value 14.

When the stored data bits DT1-DT3 have the logic values 0, 0 and 5, respectively, the switch elements T1-T6 has the threshold voltage levels VT1, VT8, VT1, VT8, VT6 and VT3, respectively, and the stored data bits DT1-DT3 have a quantized value 15.

When the stored data bits DT1-DT3 have the logic values 6, 0 and 0, respectively, the switch elements T1-T6 has the threshold voltage levels VT7, VT2, VT1, VT8, VT1 and VT8, respectively, and the stored data bits DT1-DT3 have a quantized value 16.

When the stored data bits DT1-DT3 have the logic values 0, 6 and 0, respectively, the switch elements T1-T6 has the threshold voltage levels VT1, VT8, VT7, VT2, VT1 and VT8, respectively, and the stored data bits DT1-DT3 have a quantized value 17.

When the stored data bits DT1-DT3 have the logic values 0, 0 and 6, respectively, the switch elements T1-T6 has the threshold voltage levels VT1, VT8, VT1, VT8, VT7 and VT2, respectively, and the stored data bits DT1-DT3 have a quantized value 18.

When the stored data bits DT1-DT3 have the logic values 7, 0 and 0, respectively, the switch elements T1-T6 has the threshold voltage levels VT8, VT1, VT1, VT8, VT1 and VT8, respectively, and the stored data bits DT1-DT3 have a quantized value 19.

When the stored data bits DT1-DT3 have the logic values 0, 7 and 0, respectively, the switch elements T1-T6 has the threshold voltage levels VT1, VT8, VT8, VT1, VT1 and VT8, respectively, and the stored data bits DT1-DT3 have a quantized value 20.

When the stored data bits DT1-DT3 have the logic values 0, 0 and 7, respectively, the switch elements T1-T6 has the threshold voltage levels VT1, VT8, VT1, VT8, VT8 and VT1, respectively, and the stored data bits DT1-DT3 have a quantized value 21.

FIG. 1E is a schematic diagram 100E of the memory cells performing the one-hot encoding operation, illustrated according to some embodiments of present disclosure. Referring to FIG. 1A and FIG. 1E, in the embodiment shown in FIG. 1E, the memory cells MC1-MC2 are implemented by QLC. Referring to FIG. 1B and FIG. 1E, in the embodiment shown in FIG. 1E, the positive integer n is equal to 16.

In the embodiment shown in FIG. 1E, two numbers separated by underlines correspond to the logic values of the stored data bits DT1-DT2, respectively. The memory cells MC1-MC3 can perform operations similar with the operations described in FIG. 1C and FIG. 1D, to adjust the logic values of the stored data bits DT1-DT2. For brevity, some descriptions are not repeated.

In the embodiment shown in FIG. 1E, when a stored data bit has the logic value 0, two switch elements in the corresponding memory cell have the threshold voltage levels VT1 and VT16, respectively. When the stored data bit has the logic value 1, the two switch elements in the corresponding memory cell have the threshold voltage levels VT2 and VT15, respectively. When the stored data bit has the logic value 2, the two switch elements in the corresponding memory cell have the threshold voltage levels VT3 and VT14, respectively. When the stored data bit has the logic value 3, the two switch elements in the corresponding memory cell have the threshold voltage levels VT4 and VT13, respectively. When the stored data bit has the logic value 4, the two switch elements in the corresponding memory cell have the threshold voltage levels VT5 and VT12, respectively. When the stored data bit has the logic value 5, the two switch elements in the corresponding memory cell have the threshold voltage levels VT6 and VT11, respectively. When the stored data bit has the logic value 6, the two switch elements in the corresponding memory cell have the threshold voltage levels VT7 and VT10, respectively. When the stored data bit has the logic value 7, the two switch elements in the corresponding memory cell have the threshold voltage levels VT8 and VT9, respectively. When the stored data bit has the logic value 8, the two switch elements in the corresponding memory cell have the threshold voltage levels VT9 and VT8, respectively. When the stored data bit has the logic value 9, the two switch elements in the corresponding memory cell have the threshold voltage levels VT10 and VT7, respectively. When the stored data bit has the logic value 10, the two switch elements in the corresponding memory cell have the threshold voltage levels VT11 and VT6, respectively. When the stored data bit has the logic value 11, the two switch elements in the corresponding memory cell have the threshold voltage levels VT12 and VT5, respectively. When the stored data bit has the logic value 12, the two switch elements in the corresponding memory cell have the threshold voltage levels VT13 and VT4, respectively. When the stored data bit has the logic value 13, the two switch elements in the corresponding memory cell have the threshold voltage levels VT14 and VT3, respectively. When the stored data bit has the logic value 14, the two switch elements in the corresponding memory cell have the threshold voltage levels VT15 and VT2, respectively. When the stored data bit has the logic value 15, the two switch elements in the corresponding memory cell have the threshold voltage levels VT16 and VT1, respectively.

As shown in FIG. 1E, in response to the logic values 0-15 of the stored data bits DT1 and DT2, the memory cells MC1 and MC2 can have quantized values 0-31 correspondingly.

FIG. 2A is a table 200A of the one-hot encoding of feature data, illustrated according to some embodiments of present disclosure. The feature data can be the stored feature data of the input feature data. The one-hot encoding shown in the table 200A is for SLC and MLC. In various embodiments, the feature data described in present disclosure can be implemented by other types of data, and is not limited to the feature data. For example, the stored feature data can be substituted by various types of stored data, such as stored data of image type or audio type, and the input feature data can be substituted by various types of input data, such as input data of image type or audio type.

In the embodiment shown in FIG. 2A, the feature data has 24 bits. However, the embodiments of present disclosure are not limited to this. In various embodiments, the feature data has various quantities of bits, that is, 24 can be substituted by other positive numbers. In some embodiments, the 24 bits can be implemented by a three-dimensional (3D) NAND memory string with 48 layers.

As shown in the table 200A, when the feature data has the quantized value 0, each of the 24 bits of the feature data has the logic value 0. When the feature data has the quantized value 1, the first bit of the feature data has the logic value 1, and other 23 bits of the feature data has the logic value 0. When the feature data has the quantized value 2, the second bit of the feature data has the logic value 1, and other 23 bits of the feature data has the logic value 0. When the feature data has the quantized value 3, the third bit of the feature data has the logic value 1, and other 23 bits of the feature data has the logic value 0, and so on. When the feature data has the quantized value 24, the twenty-fourth bit of the feature data has the logic value 1, and other 23 bits of the feature data has the logic value 0.

Similarly, when the feature data has the quantized value 25, the first bit of the feature data has the logic value 2, and other 23 bits of the feature data has the logic value 0. When the feature data has the quantized value 26, the second bit of the feature data has the logic value 2, and other 23 bits of the feature data has the logic value 0, and so on. When the feature data has the quantized value 48, the twenty-fourth bit of the feature data has the logic value 2, and other 23 bits of the feature data has the logic value 0.

Similarly, when the feature data has the quantized value 49, the first bit of the feature data has the logic value 3, and other 23 bits of the feature data has the logic value 0. When the feature data has the quantized value 50, the second bit of the feature data has the logic value 3, and other 23 bits of the feature data has the logic value 0, and so on. When the feature data has the quantized value 72, the twenty-fourth bit of the feature data has the logic value 3, and other 23 bits of the feature data has the logic value 0.

FIG. 2B is a table 200B of the one-hot encoding of feature data, illustrated according to some embodiments of present disclosure. Referring to FIG. 2B and FIG. 2A, the table 200B of FIG. 2B is an alternative embodiment of the table 200A of FIG. 2A. Therefore, some descriptions are not repeated brevity.

In the table 200B, the bits having the “don't care” logic value X can be used to present quantized values having ranges. The “don't care” logic value X can present different logic values. In the embodiment shown in FIG. 2B, “don't care” logic value X can present anyone of the logic values 0-3.

As shown in FIG. 2B, when the feature data has the logic values 0-2, the first and the second bits of the feature data have the “don't care” logic value X, and the other 22 bits have the logic value 0. When the feature data has the logic values 1-3, the first bit of the feature data has the logic value 1, the second and the third bits of the feature data have the “don't care” logic value X, and the other 21 bits have the logic value 0. When the feature data has the logic values 2-5, the second bit of the feature data has the logic value 1, the third to the fifth bits of the feature data have the “don't care” logic value X, and the other 20 bits have the logic value 0. When the feature data has the logic values 3-5, the third bit of the feature data has the logic value 1, the fourth to the fifth bits of the feature data have the “don't care” logic value X, and the other 21 bits have the logic value 0. When the feature data has the logic values 21-23, the twenty-third bit of the feature data has the logic value 1, the twenty-first to the twenty-second bits of the feature data have the “don't care” logic value X, and the other 21 bits have the logic value 0. When the feature data has the logic values 22-24, the twenty-fourth bit of the feature data has the logic value 1, the twenty-second to the twenty-third bits of the feature data have the “don't care” logic value X, and the other 21 bits have the logic value 0.

Similarly, when the feature data has the logic values 25-27, the first bit of the feature data has the logic value 2, the second and the third bits of the feature data have the “don't care” logic value X, and the other 21 bits have the logic value 0. When the feature data has the logic values 26-29, the second bit of the feature data has the logic value 2, the third to the fifth bits of the feature data have the “don't care” logic value X, and the other 20 bits have the logic value 0. When the feature data has the logic values 27-29, the third bit of the feature data has the logic value 2, the fourth to the fifth bits of the feature data have the “don't care” logic value X, and the other 21 bits have the logic value 0. When the feature data has the logic values 45-47, the twenty-third bit of the feature data has the logic value 2, the twenty-first to the twenty-second bits of the feature data have the “don't care” logic value X, and the other 21 bits have the logic value 0. When the feature data has the logic values 44-48, the twenty-fourth bit of the feature data has the logic value 2, the twentieth to the twenty-third bits of the feature data have the “don't care” logic value X, and the other 19 bits have the logic value 0.

Similarly, when the feature data has the logic values 49-51, the first bit of the feature data has the logic value 3, the second and the third bits of the feature data have the “don't care” logic value X, and the other 21 bits have the logic value 0. When the feature data has the logic values 50-55, the second bit of the feature data has the logic value 3, the third to the seventh bits of the feature data have the “don't care” logic value X, and the other 18 bits have the logic value 0. When the feature data has the logic values 69-70, the twenty-first bit of the feature data has the logic value 3, the twenty-second bit of the feature data have the “don't care” logic value X, and the other 22 bits have the logic value 0. When the feature data has the logic values 71-72, the twenty-third bit of the feature data has the logic value 3, the twenty-fourth bit of the feature data have the “don't care” logic value X, and the other 22 bits have the logic value 0. When the feature data has the logic values 69-72, the twenty-fourth bit of the feature data has the logic value 3, the twenty-first to the twenty-third bits of the feature data have the “don't care” logic value X, and the other 20 bits have the logic value 0.

In summary, with the “don't care” logic value X, the feature data has multiple quantized values in a range. In some embodiments, the quantized values having a range are for better matching tolerance in exact computing mode.

In some approaches, the one-hot encoding is applied to SLC, such that the number of the required NAND units for quantized values are larger, array efficiency is poor and the resolution of feature is lower.

Compared to above approaches, in the embodiments of present disclosure, the one-hot encoding is applied to MLC, to reduce the number of NAND units for quantized values, and therefore enhance the array efficiency and increase the resolution of stored feature data.

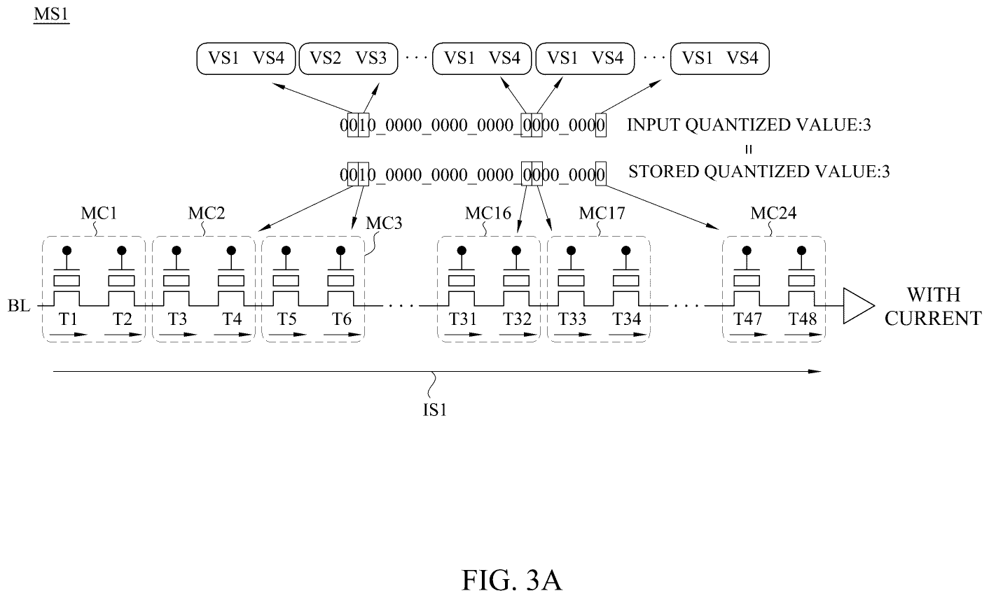

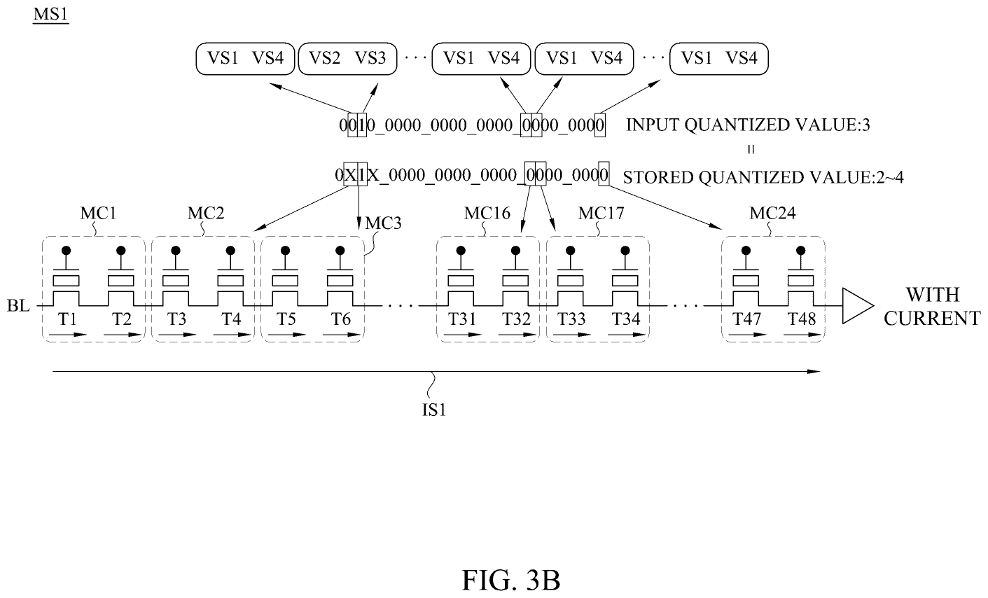

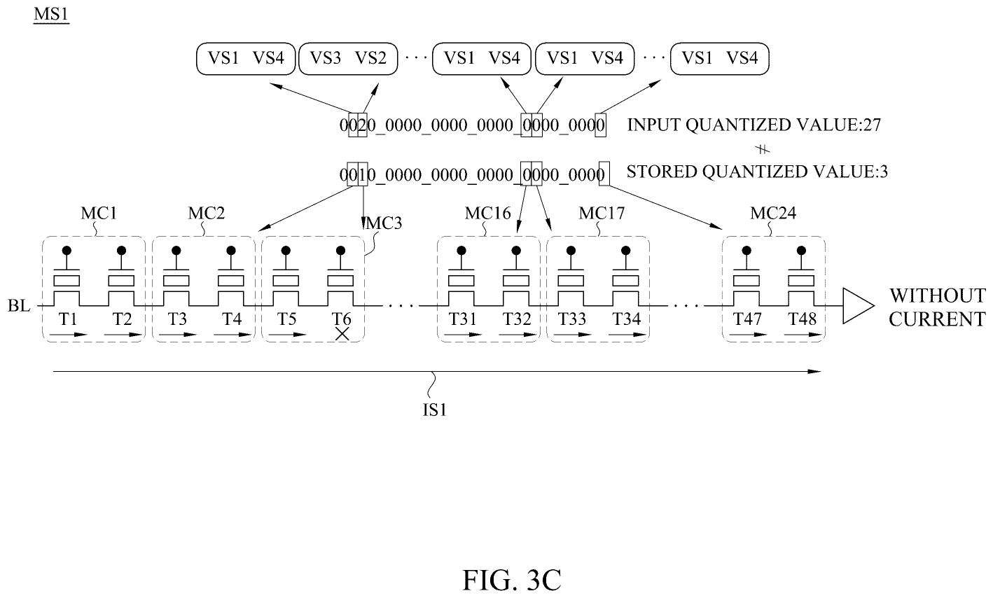

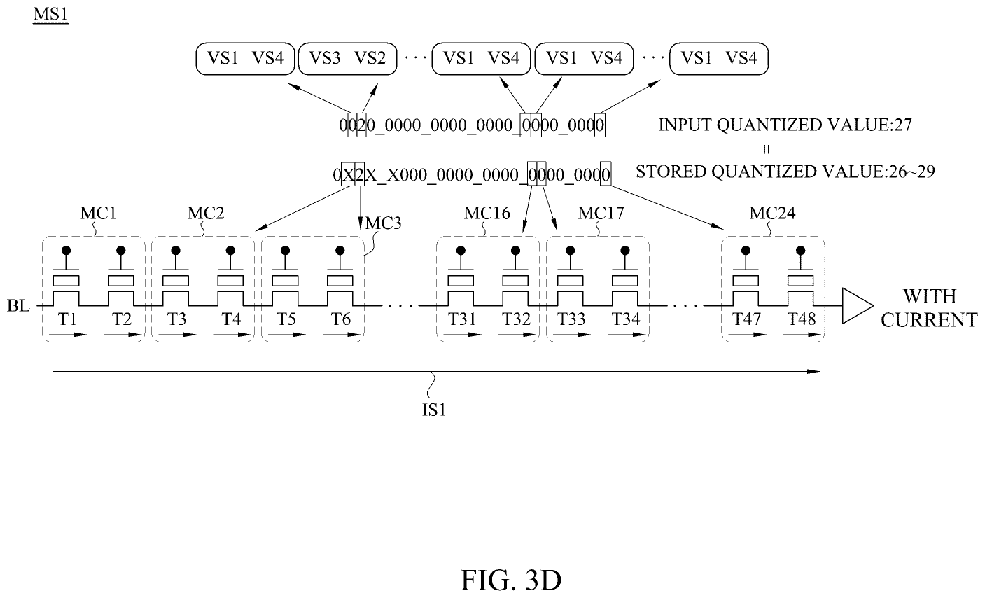

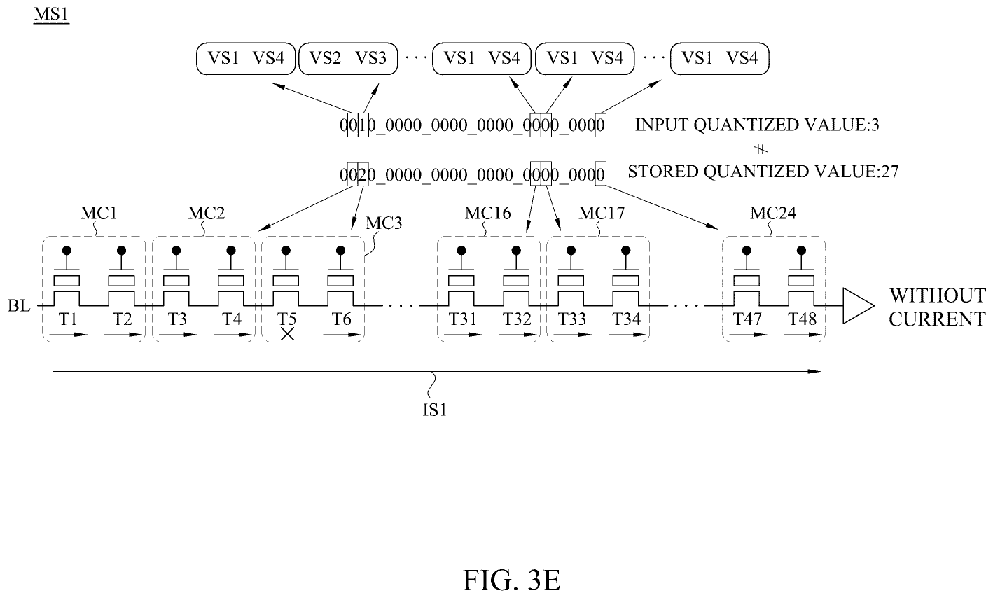

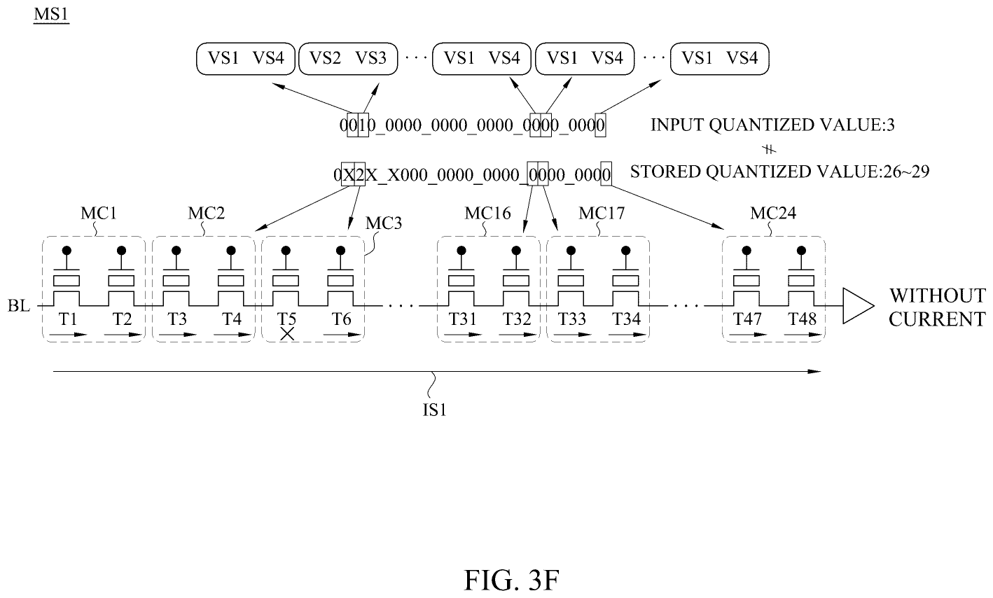

FIG. 3A is a schematic diagram of the memory string MS1 performing a search operation, illustrated according to some embodiments of present disclosure. As shown in FIG. 3A, the memory string MS1 can also include the memory cells MC4-MC24. In some embodiments, the memory cells MC4-MC24 are configured to store stored data bits DT4-DT24, respectively. However, the embodiments of present disclosure are not limited to this. In various embodiments, the memory string MS1 can includes various quantities of memory cells, that is, 24 can be substituted by other positive numbers.

The memory cell MC4 includes switch elements T7 and T8. The memory cell MC5 includes switch elements T7 and T8, and so on. The memory cell MC24 includes switch elements T47 and T48. The switch elements T1-T48 are coupled in series and are arranged in order. Referring to FIG. 1A and FIG. 3A, configurations of the switch elements T7-T48 are similar with the configurations of the switch elements T1-T6. Accordingly, some descriptions are not repeated for brevity.

In some embodiments, the control terminals of the switch elements T7-T48 are configured to receive the word line signals WL7-WL48, respectively. The word line signals WL7 and WL8 are configured to carry a search bit SB4. The word line signals WL9 and WL10 are configured to carry a search bit SB5, and so on. The word line signals WL47 and WL48 are configured to carry a search bit SB24. Alternatively stated, the word line signals WL1-WL48 are configured to carry the search bits SB1-SB24.

Referring to FIG. 1A, FIG. 1B and FIG. 3A, relationships between the search bits SB4-SB24 and the voltage levels VS1-VSn are similar with the relationships between the search bits SB1-SB3 and the voltage levels VS1-VSn. Therefore, for brevity, some descriptions are not repeated.

In some embodiments, the memory string MS1 is configured to compare stored feature data SFD1 and input feature data IFD1. The stored feature data SFD1 includes the stored data bits DT1-DT24. The input feature data IFD1 includes the input data bits SB1-SB24.

In the embodiment shown in FIG. 3A, the memory cells MC1-MC24 are implemented by MLC. However, the embodiments of present disclosure are not limited to this. In various embodiments, the memory cells MC1-MC24 can also be implemented by TLC and QLC shown in FIG. 1C and FIG. 1D.

In the embodiment shown in FIG. 3A, each of the stored data bits DT1, DT2 and DT4-DT24 has the logic value 0. Correspondingly, each of the switch elements T1, T3, T7, T9, . . . , T45 and T47 has the threshold voltage level VT1, and each of the switch elements T2, T4, T8, T10, . . . , T46 and T48 has the threshold voltage level VT4. The stored data bit DT3 has the logic value 1. Correspondingly, the switch elements T5 and T6 have the threshold voltage level VT2 and VT3, respectively. At this moment, the stored feature data SFD1 has the stored quantized value 3.

On the other hand, each of the search bits SB1, SB2 and SB4-SB24 has the logic value 0. Correspondingly, each of the word line signals WL1, WL3, WL7, WL9, . . . , WL45 and WL47 has the voltage level VS1, and each of the switch elements WL2, WL4, WL8, WL10, . . . , WL46 and WL48 has the voltage level VS4. The search bit SB3 has the logic value 1. Correspondingly, the word line signals WL5 and WL6 have the voltage level VS2 and VS3, respectively. At this moment, the input feature data IFD1 has the input quantized value 3.

In some embodiments, the memory string MS1 is configured to compare the stored quantized value of the stored bits DT1-DT24 and the input quantized value of the search bits SB1-SB24 to generate a string current signal IS1. In some embodiments, multiple memory strings are configured to sum multiple string current signals to generate a bit line signal BL.

In the embodiment shown in FIG. 3A, the quantized value 3 of the stored bits DT1-DT24 is equal to the quantized value 3 of the search bits SB1-SB24. Correspondingly, each of the switch elements T1-T48 is turned on, such that the string current signal IS1 has a current level IL1.

FIG. 3B is a schematic diagram of the memory string MS1 performing a search operation, illustrated according to some embodiments of present disclosure. Referring to FIG. 3A and FIG. 3B, the embodiment shown in FIG. 3B is an alternative embodiment of the embodiment shown in FIG. 3A. Therefore, some descriptions are not repeated brevity.

In the embodiment shown in FIG. 3B, each of the stored data bits DT1 and DT5-DT24 has the logic value 0. Correspondingly, each of the switch elements T1, T9, T11, T13, . . . , T45 and T47 has the threshold voltage level VT1, and each of the switch elements T2, T10, T12, T14, . . . , T46 and T48 has the threshold voltage level VT4. The stored data bit DT3 has the logic value 1. Correspondingly, the switch elements T5 and T6 have the threshold voltage level VT2 and VT3, respectively. Each of the stored data bits DT2 and DT4 has the “don't care” logic value X. Correspondingly, each of the switch elements T3, T4, T7 and T8 has the threshold voltage level VT1. At this moment, the stored feature data SFD1 has the stored quantized values 2-4. Alternatively stated, the stored quantized value can be 2, 3 or 4.

On the other hand, each of the search bits SB1, SB2 and SB4-SB24 has the logic value 0. The search bit SB3 has the logic value 1. At this moment, the input feature data IFD1 has the input quantized value 3.

In the embodiment shown in FIG. 3B, the quantized value 3 of the stored bits DT1-DT24 is equal to the quantized value 3 of the search bits SB1-SB24. Correspondingly, each of the switch elements T1-T48 is turned on, such that the string current signal IS1 has the current level IL1.

FIG. 3C is a schematic diagram of the memory string MS1 performing a search operation, illustrated according to some embodiments of present disclosure. Referring to FIG. 3A and FIG. 3C, the embodiment shown in FIG. 3C is an alternative embodiment of the embodiment shown in FIG. 3A. Therefore, some descriptions are not repeated brevity.

In the embodiment shown in FIG. 3C, each of the stored data bits DT1, DT2 and DT4-DT24 has the logic value 0. The stored data bit DT3 has the logic value 1. At this moment, the stored feature data SFD1 has the stored quantized value 3.

On the other hand, each of the search bits SB1, SB2 and SB4-SB24 has the logic value 0. Correspondingly, each of the word line signals WL1, WL3, WL7, WL9, . . . , WL45 and WL47 has the voltage level VS1, and each of the switch elements WL2, WL4, WL8, WL10, . . . , WL46 and WL48 has the voltage level VS4. The search bit SB3 has the logic value 2. Correspondingly, the word line signals WL5 and WL6 have the voltage level VS3 and VS2, respectively. At this moment, the input feature data IFD1 has the input quantized value 27.

In the embodiment shown in FIG. 3C, the quantized value 3 of the stored bits DT1-DT24 is different from the quantized value 27 of the search bits SB1-SB24. At this moment, each of the switch elements T1-T5 and T7-T48 is turned on. The switch element T6 having the threshold voltage level VT3 is turned off in response to the word line signal WL6 having the voltage level VS2, such that the string current signal IS1 has a current level IL2. In some embodiments, the current level IL2 is smaller than the current level IL1, and is referred to as a mismatching current level. In some embodiments, the current level IL2 is the zero current level. Alternatively stated, in such condition, the memory string MS1 is without current.

FIG. 3D is a schematic diagram of the memory string MS1 performing a search operation, illustrated according to some embodiments of present disclosure. Referring to FIG. 3C and FIG. 3D, the embodiment shown in FIG. 3D is an alternative embodiment of the embodiment shown in FIG. 3C. Therefore, some descriptions are not repeated brevity.

In the embodiment shown in FIG. 3D, each of the stored data bits DT1 and DT6-DT24 has the logic value 0. Correspondingly, each of the switch elements T1, T11, T13, T15, . . . , T45 and T47 has the threshold voltage level VT1, and each of the switch elements T2, T12, T14, T16, . . . , T46 and T48 has the threshold voltage level VT4. The stored data bit DT3 has the logic value 2. Correspondingly, the switch elements T5 and T6 have the threshold voltage levels VT3 and VT2, respectively. Each of the stored data bits DT2, DT4 and DT5 has the “don't care” logic value X. Correspondingly, each of the switch elements T3, T4, T7, T8, T9 and T10 has the threshold voltage level VT1. At this moment, the stored feature data SFD1 has the stored quantized values 26-29. Alternatively stated, the stored quantized value can be 26, 27, 28 or 29.

On the other hand, each of the search bits SB1, SB2 and SB4-SB24 has the logic value 0. The search bit SB3 has the logic value 2. At this moment, the input feature data IFD1 has the input quantized value 27.

In the embodiment shown in FIG. 3D, the quantized value 27 of the stored bits DT1-DT24 is equal to the quantized value 27 of the search bits SB1-SB24. Correspondingly, each of the switch elements T1-T48 is turned on, such that the string current signal IS1 has the current level IL1.

FIG. 3E is a schematic diagram of the memory string MS1 performing a search operation, illustrated according to some embodiments of present disclosure. Referring to FIG. 3A and FIG. 3E, the embodiment shown in FIG. 3E is an alternative embodiment of the embodiment shown in FIG. 3A. Therefore, some descriptions are not repeated brevity.

In the embodiment shown in FIG. 3E, each of the stored data bits DT1, DT2 and DT4-DT24 has the logic value 0. The stored data bit DT3 has the logic value 2. At this moment, the stored feature data SFD1 has the stored quantized value 27.

On the other hand, each of the search bits SB1, SB2 and SB4-SB24 has the logic value 0. The search bit SB3 has the logic value 1. At this moment, the input feature data IFD1 has the input quantized value 3.

In the embodiment shown in FIG. 3E, the quantized value 27 of the stored bits DT1-DT24 is different from the quantized value 3 of the search bits SB1-SB24. At this moment, each of the switch elements T1-T4 and T6-T48 is turned on. The switch element T5 having the threshold voltage level VT3 is turned off in response to the word line signal WL5 having the voltage level VS2, such that the string current signal IS1 has the current level IL2. Alternatively stated, in such condition, the memory string MS1 is without current.

FIG. 3F is a schematic diagram of the memory string MS1 performing a search operation, illustrated according to some embodiments of present disclosure. Referring to FIG. 3D and FIG. 3F, the embodiment shown in FIG. 3F is an alternative embodiment of the embodiment shown in FIG. 3D. Therefore, some descriptions are not repeated brevity.

In the embodiment shown in FIG. 3F, each of the stored data bits DT1 and DT6-DT24 has the logic value 0. The stored data bit DT3 has the logic value 2. The stored data bits DT2, DT3 and DT5 have the “don't care” logic value X. At this moment, the stored feature data SFD1 has the stored quantized values 26-29.

On the other hand, each of the search bits SB1, SB2 and SB4-SB24 has the logic value 0. The search bit SB3 has the logic value 1. At this moment, the input feature data IFD1 has the input quantized value 3.

In the embodiment shown in FIG. 3F, the quantized values 26-29 of the stored bits DT1-DT24 are different from the quantized value 3 of the search bits SB1-SB24. At this moment, each of the switch elements T1-T4 and T6-T48 is turned on. The switch element T5 having the threshold voltage level VT3 is turned off in response to the word line signal WL5 having the voltage level VS2, such that the string current signal IS1 has the current level IL2. Alternatively stated, in such condition, the memory string MS1 is without current.

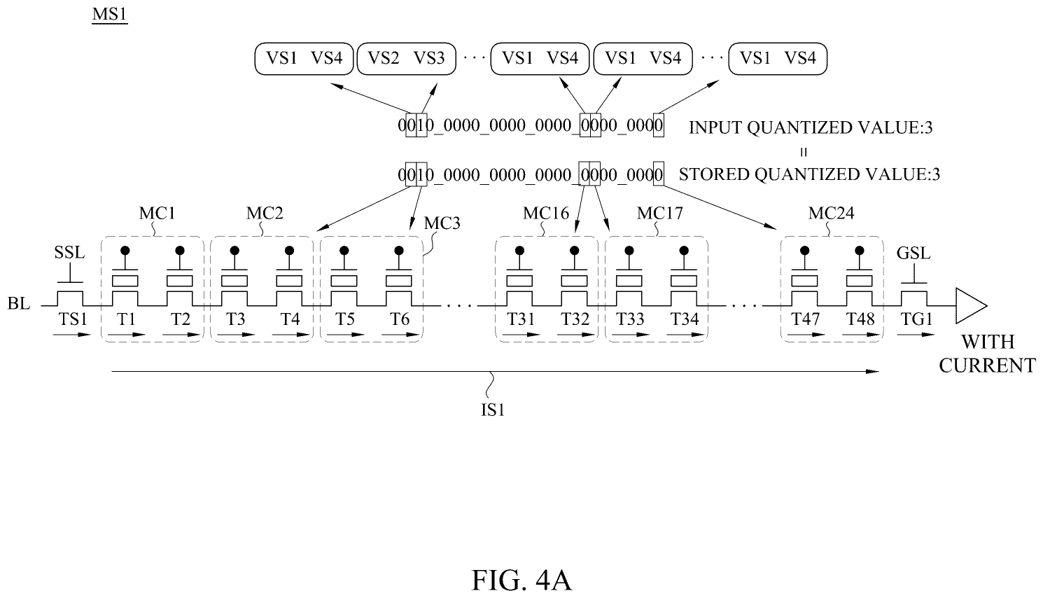

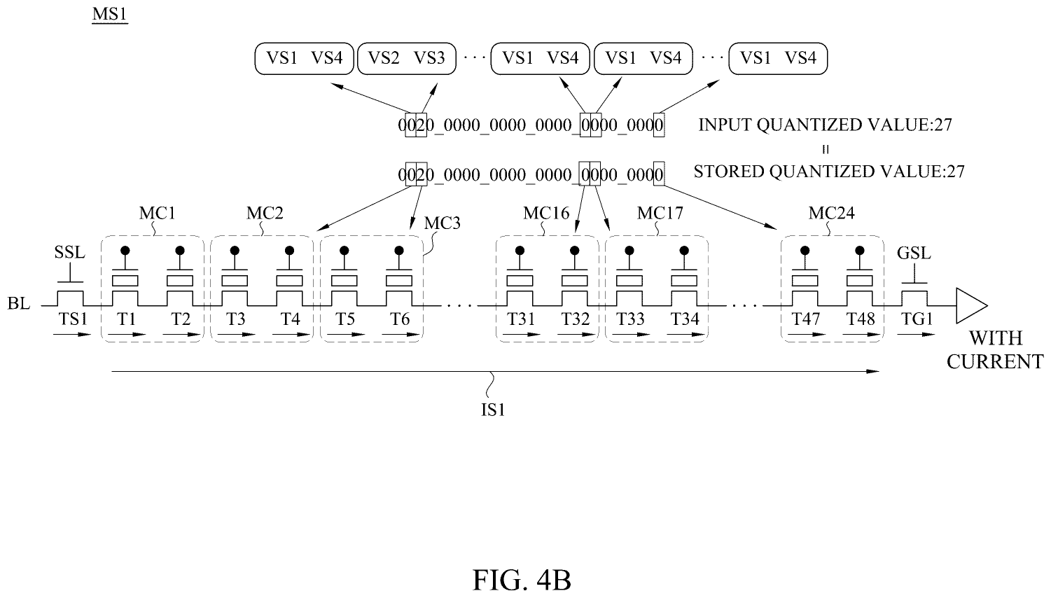

In some embodiments, when the stored quantized value and the input quantized value are match with each other, the string current signal IS1 has the current level IL1. Correspondingly, the current level IL1 can be referred to as the matching current level. Due to device variation, the matching current level may be different. In some embodiments, the current clamping technology can be used to solve the matching current variation. Details regarding the current clamping technology are described below with the embodiments associated with FIG. 4A and FIG. 4B.

FIG. 4A is a schematic diagram of the memory string MS1 performing a search operation, illustrated according to some embodiments of present disclosure. Referring to FIG. 4A and FIG. 3A, the embodiment shown in FIG. 4A is an alternative embodiment of the embodiment shown in FIG. 3A. Therefore, some descriptions are not repeated brevity.

Compared to FIG. 3A, in the embodiment shown in FIG. 4A, the memory string MS1 further comprises switch elements TS1 and TG1. The switch elements TS1 and TG1 are coupled in series with the switch elements T1-T48. The switch elements T1-T48 are arranged between the switch elements TS1 and TG1. The control terminals of the switch elements TS1 and TG1 are configured to receive a string select line signal SSL and a ground select line signal GSL.

In some embodiments, the switch elements T1-T48 are implemented by switch elements with charge trap, such as flash cells. The switch elements TS1 and TG1 are implemented by trapping free switch elements, such as metal-oxide-semiconductor (MOS) transistor.

In the embodiment shown in FIG. 4A, each of the stored data bits DT1, DT2 and DT4-DT24 has the logic value 0. The stored data bit DT3 has the logic value 1. At this moment, the stored feature data SFD1 has the stored quantized value 3.

On the other hand, each of the search bits SB1, SB2 and SB4-SB24 has the logic value 0. The stored data bit SB3 has the logic value 1. At this moment, the input feature data IFD1 has the input quantized value 3.

In response to the stored quantized value 3 being equal to the input quantized value 3, the string current signal IS1 has the current level IL1. At this moment, each of the string select line signal SSL and the ground select line signal GSL has a clamp voltage level, to clamp the string current signal IS1, such the variation of the current level IL1 is reduced.

In some embodiments, the gate bias of each of the string select line signal SSL and the ground select line signal GSL is tunable. In various embodiments, the string select line signal SSL and the ground select line signal GSL can be used simultaneously to clamp the string current signal IS1, and can also only use one of the string select line signal SSL and the ground select line signal GSL to clamp the string current signal IS1.

FIG. 4B is a schematic diagram of the memory string MS1 performing a search operation, illustrated according to some embodiments of present disclosure. Referring to FIG. 4B and FIG. 4A, the embodiment shown in FIG. 4B is an alternative embodiment of the embodiment shown in FIG. 4A. Therefore, some descriptions are not repeated brevity.

In the embodiment shown in FIG. 4B, each of the stored data bits DT1, DT2 and DT4-DT24 has the logic value 0. The stored data bit DT3 has the logic value 2. At this moment, the stored feature data SFD1 has the stored quantized value 27.

On the other hand, each of the search bits SB1, SB2 and SB4-SB24 has the logic value 0. The stored data bit SB3 has the logic value 2. At this moment, the input feature data IFD1 has the input quantized value 27.

In response to the stored quantized value 27 being equal to the input quantized value 27, the string current signal IS1 has the current level IL1. At this moment, each of the string select line signal SSL and the ground select line signal GSL has the clamp voltage level, to clamp the string current signal IS1, such the variation of the current level IL1 is reduced.

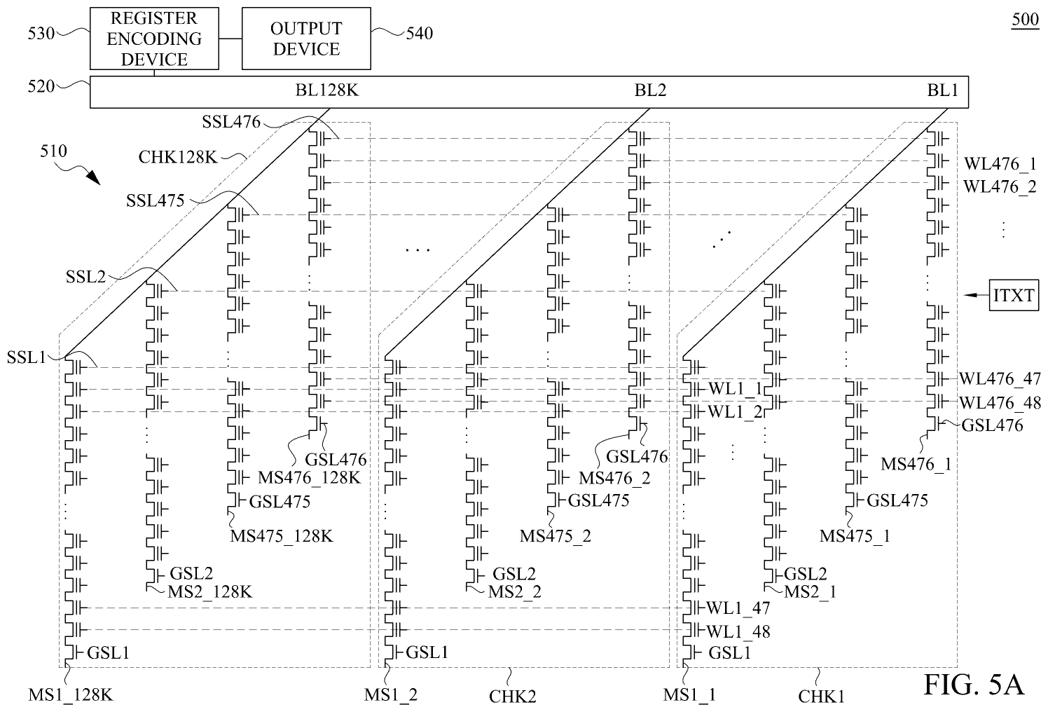

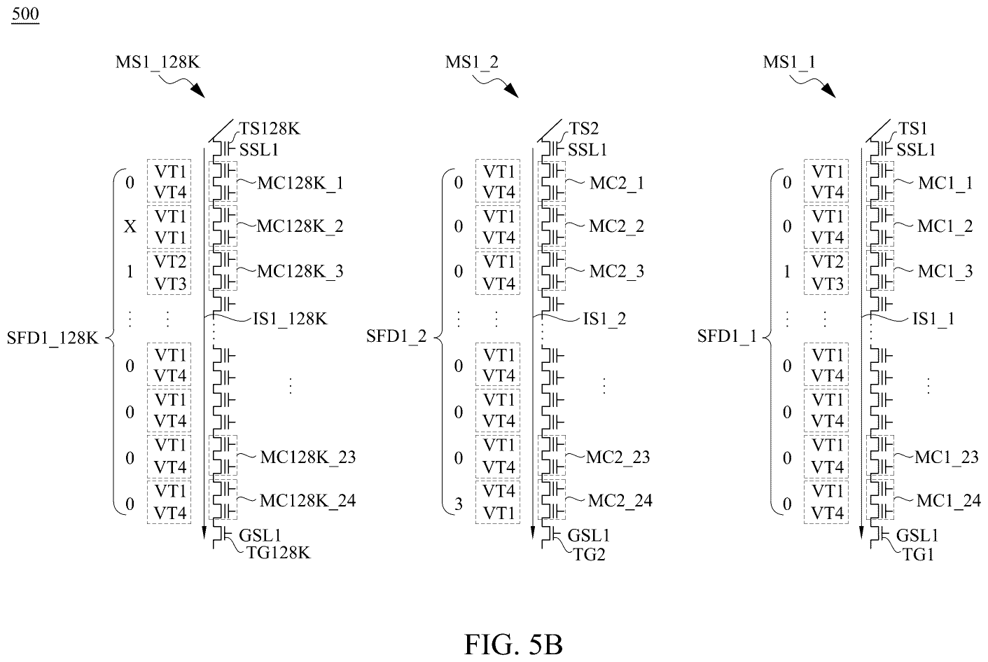

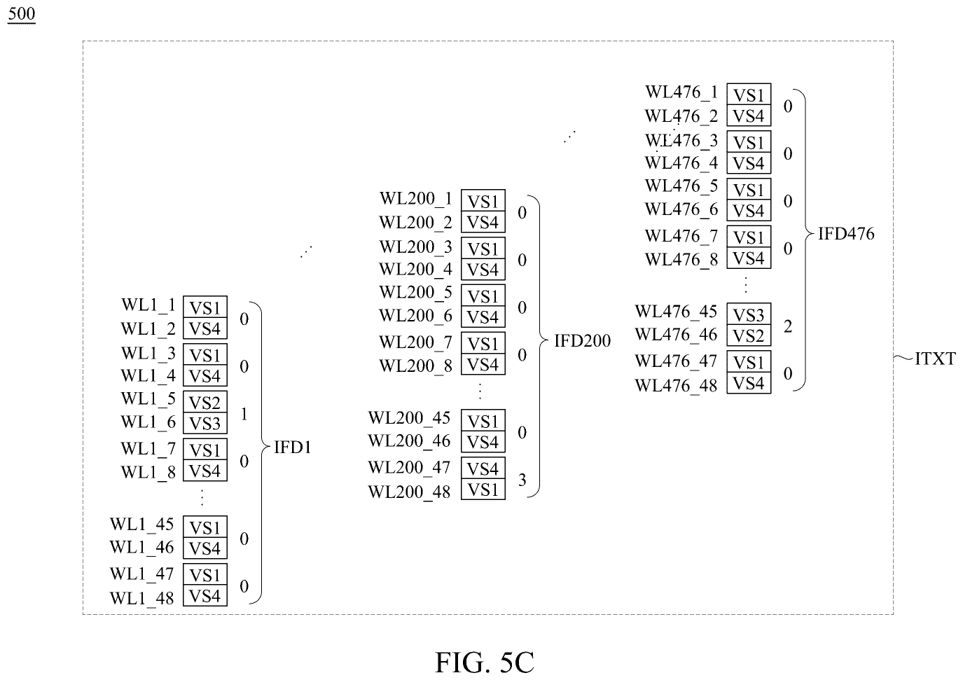

FIG. 5A is a schematic diagram of a memory system 500 illustrated according to some embodiments of present disclosure. As shown in FIG. 5A, the memory system 500 includes a memory device 510, a sensing device 520, a register encoding device 530 and an output device 540. In various embodiments, the memory device 510 can be implemented by three-dimensional NAND memory array. Referring to FIG. 1A and FIG. 5A, the memory device 510 is an alternative embodiment of the memory device 100. Therefore, for brevity, some descriptions are not repeated.

In some embodiments, the memory device 510 is configured to generate bit line signals BL1-BL128K, in which K in 128K represents one thousand. However, the present disclosure is not limited to this. In various embodiments, the memory device 510 can generate various quantities of bit line signals, that is, 128K can be substituted by other positive integers. The sensing device 520 can include a page buffer and a sensing amplifier, and configured to sense corresponding searching results of the bit line signals BL1-BL128K. The register encoding device 530 can includes cache registers and priority encoders. The output device 540 is configured to output the matching results of the memory device 510.

In some embodiments, the process performed by the register encoding device 530 to the bit line signals includes logic processes of AND logic, OR logic or counting, and also may include combining processes of the three logic processes described above. Referring to FIG. 1A to FIG. 5A, the register encoding device 530 can receive sense results from the memory device 100 and/or 510, and controls sequencing (whether serial or parallel) and combines sense results to produce overall search results as the matching results outputted from the output device 540.

In some embodiments, the register encoding device 530 is further configured to perform priority encoding to the corresponding searching results of the bit line signals BL1-BL128K. For example, the register encoding device 530 collectively processes the corresponding searching results of the bit line signals BL1-BL128K, and preferentially select an address of a bit line signal corresponding to the best searching result (that is, the input feature data and the stored feature data are equal to each other).

As shown in FIG. 5A, the memory device includes multiple memory chunks CHK1-CHK128K. The memory chunks CHK1-CHK128K are configured to store stored texts TXT1-TXT128K, respectively. In some embodiments, the memory chunks CHK1-CHK128K are referred to as text chunks. The stored texts TXT1 includes stored feature data SFD1_1-SFD476_1. The stored texts TXT2 includes stored feature data SFD1_2-SFD476_2, and so on. The stored texts TXT128K includes stored feature data SFD1_128K-SFD476_128K.

The memory chunk CHK1 includes memory strings MS1_1-MS476_1. The memory chunk CHK2 includes memory strings MS1_2-MS476_2, and so on. The memory chunk CHK128K includes memory strings MS1_128K-MS476_128K. However, the present disclosure is not limited to this. In various embodiments, the memory chunk can include various quantities of memory strings, that is, 476 can be substituted by other positive integers.

In some embodiments, the memory strings MS1_1-MS476_1 are configured to store the stored feature data SFD1_1-SFD476_1, respectively. The memory strings MS1_2-MS476_2 are configured to store the stored feature data SFD1_2-SFD476_2, respectively, and so on. The memory strings MS1_128K-MS476_128K are configured to store the stored feature data SFD1_128K-SFD476_128K, respectively.

In the embodiment shown in FIG. 5A, each memory string includes 24 memory cells. Alternatively stated, each stored feature data has 24 stored data bits. However, the present disclosure is not limited to this. In various embodiments, the memory string can include various quantities of memory cells, that is, 24 can be substituted by other positive integers.

In some embodiments, the memory chunks CHK1-CHK128K are configured to receive word line signals carrying an input text ITXT, to compare each of the stored texts TXT1-TXT128K with the input text ITXT. The input text ITXT includes input feature data IFD1-IFD476.

Specifically, each of the memory strings MS1_1-MS1_128K is configured to receive word line signals WL1_1-WL1_48. Each of the memory strings MS2_1-MS2_128K is configured to receive word line signals WL2_1-WL2_48, and so on. Each of the memory strings MS476_1-MS476_128K is configured to receive word line signals WL476_1-WL476_48.

In some embodiments, the word line signals WL1_1-WL1_48 are configured to carry the input feature data IFD1. The word line signals WL2_1-WL2_48 are configured to carry the input feature data IFD2, and so on. The word line signals WL476_1-WL476_48 are configured to carry the input feature data IFD476.

During the search operation, the memory string MS1_1 is configured to compare the stored feature data SFD1_1 with the input feature data IFD1 to generate a string current signal IS1_1. The memory string MS2_1 is configured to compare the stored feature data SFD2_1 with the input feature data IFD2 to generate a string current signal IS2_1, and so on. The memory string MS475_1 is configured to compare the stored feature data SFD475_1 with the input feature data IFD475 to generate a string current signal IS475_1. The memory string MS476_1 is configured to compare the stored feature data SFD476_1 with the input feature data IFD476 to generate a string current signal IS476_1.

Similarly, the memory string MS1_2 is configured to compare the stored feature data SFD1_2 with the input feature data IFD1 to generate a string current signal IS1_2. The memory string MS2_2 is configured to compare the stored feature data SFD2_2 with the input feature data IFD2 to generate a string current signal IS2_2, and so on. The memory string MS475_2 is configured to compare the stored feature data SFD475_2 with the input feature data IFD475 to generate a string current signal IS475_2. The memory string MS476_2 is configured to compare the stored feature data SFD476_2 with the input feature data IFD476 to generate a string current signal IS476_2, and so on.

Similarly, the memory string MS1_128K is configured to compare the stored feature data SFD1_128K with the input feature data IFD1 to generate a string current signal IS1_128K. The memory string MS2_128K is configured to compare the stored feature data SFD2_128K with the input feature data IFD2 to generate a string current signal IS2_128K, and so on. The memory string MS475_128K is configured to compare the stored feature data SFD475_128K with the input feature data IFD475 to generate a string current signal IS475_128K. The memory string MS476_128K is configured to compare the stored feature data SFD476_128K with the input feature data IFD476 to generate a string current signal IS476_128K.

Referring to FIG. 3A to FIG. 3F and FIG. 5A, the search operation of the memory strings in the memory device 510 comparing the stored feature data and the input feature data are similar with the search operations shown in FIG. 3A to FIG. 3F. Therefore, for brevity, some descriptions are not repeated.

Then, the memory chunk CHK1 is configured to sum the string current signals IS1_1-IS476_1 to generate the bit line signal BL1. The memory chunk CHK2 is configured to sum the string current signals IS1_2-IS476_2 to generate the bit line signal BL2, and so on. The memory chunk CHK128K is configured to sum the string current signals IS1_128K-IS476_128K to generate the bit line signal BL128K.

In the condition shown in FIG. 5A, each of the string current signals IS1_1-IS476_1 has the matching current level IL1. Each of the string current signals IS1_2-IS476_2 has the mismatching current level IL2. Each of the string current signals IS1_128K and IS2_128K has the matching current level IL1, and each of the string current signals IS3_128K and IS476_128K has the mismatching current level IL2.

Correspondingly, a current level of the bit line signal BL1 is larger than a current level of the bit line signal BL128K, and the current level of the bit line signal BL128K is larger than a current level of the bit line signal BL2. Alternatively stated, a similarity between the input text ITXT and the stored text TXT1 is larger than a similarity between the input text ITXT and the stored text TXT128K, and the similarity between the input text ITXT and the stored text TXT128K is larger than a similarity between the input text ITXT and the stored text TXT2.

As shown in FIG. 5A, the memory device 510 further includes switch elements configured to receive string select line signals SSL1-SSL476 and ground select line signals GSL1-GSL476. During the search operation, each of the string select line signals SSL1-SSL476 and the ground select line signals GSL1-GSL476 has the clamp voltage level, to clamp corresponding string current signals.

Referring to FIG. 4A, FIG. 4B and FIG. 5A, the operation of the memory device 510 clamping the string current signals by the string select line signals SSL1-SSL476 and the ground select line signals GSL1-GSL476 is similar with the operation shown in FIG. 4A to FIG. 4B. Therefore, for brevity, some descriptions are not repeated.

FIG. 5B is a schematic diagram of further details of the memory system 500 performing the search operation, illustrated according to some embodiments of present disclosure. In the embodiment shown in FIG. 5B, the stored feature data SFD1_1 has the quantized value 3, the stored feature data SFD1_2 has the quantized value 73, and the stored feature data SFD1_128K has the quantized values 2-3.

As shown in FIG. 5B, the memory string MS1_1 includes switch elements TS1, TG1 and memory cells MC1_1-MC1_24. The memory string MS1_2 includes switch elements TS2, TG2 and memory cells MC2_1-MC2_24, and so on. The memory string MS1_128K includes switch elements TS128K, TG128K and memory cells MC128K_1-MC128K_24. Each of the switch elements TS1-TS128K is configured to receive the string select line SSL1, and each of the switch elements TG1-TG128K is configured to receive the ground select line GSL1.

In some embodiments, the memory cell MC1_1 includes switch elements T1_1 and T1_2. The memory cell MC1_2 includes switch elements T1_3 and T1_4, and so on. The memory cell MC1_24 includes switch elements T1_47 and T1_48. The memory cell MC2_1 includes switch elements T2_1 and T2_2. The memory cell MC2_2 includes switch elements T2_3 and T2_4, and so on. The memory cell MC2_24 includes switch elements T2_47 and T2_48. The memory cell MC128K_1 includes switch elements T128K_1 and T128K_2. The memory cell MC128K_2 includes switch elements T128K_3 and T128K_4, and so on. The memory cell MC128K_24 includes switch elements T128K_47 and T128K_48.

Alternatively stated, the memory string MS1_1 includes the switch elements T1_1-T1_48 coupled in series. The memory string MS2_1 includes the switch elements T2_1-T2_48 coupled in series. The memory string MS128K_1 includes the switch elements T128K_1-T128K_48 coupled in series.

In response to the stored feature data SFD1_1 having the quantized value 3, each of the switch elements T1_1, T1_3, T1_7, T1_9, . . . , T1_45 and T1_47 has the threshold voltage level VT1. Each of the switch elements T1_2, T1_4, T1_8, T1_10, . . . , T1_46 and T1_48 has the threshold voltage level VT4. The switch elements T1_5 and T1_6 have the threshold voltage levels VT2 and VT3, respectively.

In response to the stored feature data SFD1_2 having the quantized value 73, each of the switch elements T2_1, T2_3, T2_5, T2_7, . . . , T2_43, T2_45 and T2_48 has the threshold voltage level VT1. Each of the switch elements T2_2, T2_4, T2_6, T2_8, . . . , T2_44, T2_46 and T2_47 has the threshold voltage level VT4.

In response to the stored feature data SFD1_128K having the quantized values 2-3, each of the switch elements T128K_1, T128K_3, T128K_4, T128K_7, T128K_9, . . . , T128K_45 and T128K_47 has the threshold voltage level VT1. Each of the switch elements T128K_2, T128K_8, T128K_10, . . . , T128K_46 and T128K_48 has the threshold voltage level VT4. The switch elements T128K_5 and T128K_6 have the threshold voltage levels VT2 and VT3, respectively.

FIG. 5C is a schematic diagram of further details of the memory system 500 performing the search operation, illustrated according to some embodiments of present disclosure. In the embodiment shown in FIG. 5C, the input feature data IFD1 has the quantized value 3, the input feature data IFD200 has the quantized value 72, and the input feature data IFD476 has the quantized value 47.

In response to the input feature data IFD1 having the quantized value 3, each of the word line signals WL1_1, WL1_3, WL1_7, WL1_9, . . . , WL1_45 and WL1_47 has the voltage level VS1. Each of the word line signals WL1_2, WL1_4, WL1_8, WL1_10, . . . , WL1_46 and WL1_48 has the voltage level VS4. The word line signals WL1_5 and WL1_6 have the voltage levels VS2 and VS3, respectively.

In response to the input feature data IFD200 having the quantized value 72, each of the word line signals WL200_1, WL200_3, WL200_5, WL200_7, . . . , WL200_43, WL200_45 and WL200_48 has the voltage level VS1. Each of the word line signals WL200_2, WL200_4, WL200_6, WL200_8, . . . , WL200_44, WL200_46 and WL200_47 has the voltage level VS4.

In response to the input feature data IFD476 having the quantized value 47, each of the word line signals WL476_1, WL476_3, WL476_5, WL476_7, . . . , WL476_41, WL476_43 and WL476_47 has the voltage level VS1. Each of the word line signals WL476_2, WL476_4, WL476_6, WL476_8, . . . , WL476_42, WL476_44 and WL476_48 has the voltage level VS4. The word line signals WL476_45 and WL476_46 have the voltage levels VS3 and VS2, respectively.

Referring to FIG. 5B and FIG. 5C, the memory string MS1_1 is configured to compare the stored feature data SFD1_1 and the input feature data IFD1 to generate the string current signal IS1_1. In response to the quantized value 3 of the stored feature data SFD1_1 being equal to the quantized value 3 of the input feature data IFD1, the string current signal IS1_1 has the matching current level IL1.

Similarly, the memory string MS1_2 is configured to compare the stored feature data SFD1_2 and the input feature data IFD1 to generate the string current signal IS1_2. In response to the quantized value 73 of the stored feature data SFD1_2 being different from the quantized value 3 of the input feature data IFD1, the string current signal IS1_2 has the mismatching current level IL2.

Similarly, the memory string MS1_128K is configured to compare the stored feature data SFD1_128K and the input feature data IFD1 to generate the string current signal IS1_128K. In response to the quantized value 3 of the stored feature data SFD1_128K being equal to the quantized value 3 of the input feature data IFD1, the string current signal IS1_128K has the matching current level IL1.

In some embodiments, the memory cells in present disclosure are referred to as in-memory searching (IMS) cells. In various embodiments, the IMS cells can be implemented by floating gate memory, split-gate memory, silicon-oxide-nitride-oxide-silicon (SONOS) memory, floating dot memory, dynamic random-access memory (DRAM) and/or ferroelectric field-effect transistor (FeFET).

In various embodiments, the memory device 510 can be implemented by various structures, such as 2D-NAND flash structure, 3D-NAND flash structure, 2D-NOR flash structure or 3D-NOR flash structure.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A memory device, comprising:
a memory string configured to stored store data, and compare input data with the store data to generate a string current signal,
wherein the memory string comprises a plurality of memory cells,
the plurality of memory cells comprises a plurality of switch elements coupled in series,
when a quantized value of the input data is equal to a quantized value of the stored data, a first switch element of the plurality of switch elements is turned on and the string current signal has a first current level, and
when the quantized value of the input data is different from the quantized value of the stored data, the first switch element of the plurality of switch elements is turned off and the string current signal has a second current level lower than the first current level.

2. The memory device of claim 1, wherein the memory string comprises a first memory cell and a second memory cell,
the first memory cell comprises the first switch element and a second switch element,
the second memory cell comprises a third switch element and a fourth switch element,
when the first memory cell and the second memory cell have a first logic value and a second logic value respectively, the third switch element, the second switch element, the first switch element and the fourth switch element have a first threshold voltage level, a second threshold voltage level, a third threshold voltage level, and a fourth threshold voltage level, respectively, and
the first threshold voltage level, the second threshold voltage level, the third threshold voltage level, and the fourth threshold voltage level are different from each other.

3. The memory device of claim 2, wherein the first switch element, the second switch element, the third switch element and the fourth switch element are configured to receive a first word line signal, a second word line signal, a third word line signal and a fourth word line signal, respectively,
the first word line signal and the second word line signal are configured to carry a first search bit,
the third word line signal and the fourth word line signal are configured to carry a second search bit, and
when the second search bit has the second logic value, each of the first search bit and the first memory cell has the first logic value, and each of the third switch element and the fourth switch element has the first threshold voltage level, the string current signal has the first current level.

4. The memory device of claim 3, wherein the first logic value is larger than the second logic value.

5. The memory device of claim 3, wherein when the first search bit has a third logic value and the first memory cell has the first logic value, the first switch element is turned off, and
the third logic value is larger than the first logic value.

6. The memory device of claim 5, wherein when the first search bit has the first logic value and the first memory cell has the third logic value, the second switch element is turned off.

7. The memory device of claim 5, wherein when the second search bit has the second logic value, each of the first search bit and the first memory cell has the third logic value, and each of the third switch element and the fourth switch element has the first threshold voltage level, the string current signal has the first current level.

8. The memory device of claim 5, wherein when the first search bit and the first memory cell have the first logic value and the third logic value, respectively, the string current signal has the second current level.

9. The memory device of claim 5, wherein when the second search bit has the second logic value and each of the third switch element and the fourth switch element has the first threshold voltage level, each of the third switch element and the fourth switch element is turned on.

10. The memory device of claim 1, wherein the memory string further comprises at least one switch element coupled in series with the plurality of switch elements, and
at least one control terminal of the at least one switch element has a clamp voltage level, to clamp the string current signal.

11. A memory device, comprising:
a memory string configured to store stored data, and configured to receive a plurality of word line signals carrying input data, to compare the input data with the stored data to generate a string current signal,
wherein the memory string comprises a first memory cell,
the first memory cell comprises a first switch element and a second switch element coupled in series,
the first switch element and the second switch element are configured to receive a first word line signal of the plurality of word line signals and a second word line signal of the plurality of word line signals, respectively,
when the stored data have a first quantized value, the first switch element and the second switch element respectively have a first threshold voltage level and a second threshold voltage level,
when the input data have the first quantized value, the first word line signal and the second word line signal respectively have a first voltage level and a second voltage level, and
when the input data have a second quantized value different from the first quantized value, the first word line signal and the second word line signal respectively have the second voltage level and the first voltage level.

12. The memory device of claim 11, wherein when the stored data and the input data have the first quantized value and the second quantized value, respectively, the second switch element is turned off and the first switch element is turned on.

13. The memory device of claim 12, wherein when the stored data and the input data have the second quantized value and the first quantized value, respectively, the first switch element is turned off and the second switch element is turned on.

14. The memory device of claim 11, wherein when each of the stored data and the input data has the first quantized value, the string current signal has a first current level, and
when the stored data and the input data have the first quantized value and the second quantized value, respectively, the string current signal has a second current level smaller than the first current level.

15. The memory device of claim 14, wherein the first word line signal and the second word line signal are configured to carry a first search bit,
the memory string further comprises a second memory cell,
the second memory cell comprises a third switch element and a fourth switch element coupled in series,
the third switch element and the fourth switch element are configured to receive a third word line signal and a fourth word line signal of the plurality of word line signals, respectively,
the third word line signal and the fourth word line signal are configured to carry a second search bit,
when the second memory cell has a first logic value, each of the third switch element and the fourth switch element has a third threshold voltage level, and
the third threshold voltage level is smaller than each of the first threshold voltage level and the second threshold voltage level.

16. The memory device of claim 15, wherein when the second memory cell has the first logic value, the second search bit has a second logic value, and each of the first memory cell and the first search bit has a third logic value, the string current signal has the first current level, and
the first logic value, the second logic value and the third logic value are different from each other.

17. The memory device of claim 15, wherein when the second memory cell has the first logic value, the second search bit has a second logic value, and the first memory cell and the first search bit have a third logic value and a fourth logic value, respectively, the string current signal has the second current level, and
the first logic value, the second logic value, the third logic value and the fourth logic value are different from each other.

18. A memory system, comprising:
a plurality of memory chunks configured to receive a plurality of string select line signals,
wherein the plurality of memory chunks at least comprise a first memory string configured to store first stored data and a second memory string configured to store second stored data,
the first memory string is configured to compare the first stored data and input data to generate a first string current signal,
the second memory string is configured to compare the second stored data and the input data to generate a second string current signal,
in response to a quantized value of the input data being equal to a quantized value of the first stored data, the first string current signal has a first current level, and
in response to the quantized value of the input data being different from the quantized value of the second stored data, the second string current signal has a second current level lower than the first current level.

19. The memory system of claim 18, wherein the plurality of memory chunks further comprise a third memory string configured to store third stored data, and
the third memory string is configured to compare the third stored data and the input data to generate a third string current signal.

20. The memory system of claim 19, wherein the first memory string includes a first memory cell and a second memory cell,
the third memory string includes a third memory cell and a fourth memory cell,
when the first memory cell has a first logic value, each of the second memory cell and the fourth memory cell has a second logic value, and the third memory cell has a third logic value, each of the first string current signal and the third string current signal has the first current level, and
the first logic value, the second logic value and the third logic value are different from each other.
